(19) United States
(12) Patent Application Publication
(10) Pub. No.: US 2015/0101667 A1
(43) Pub. Date: Apr. 16, 2015

(54) CONCENTRATOR FOR POLYCHROMATIC LIGHT

(71) Applicant: LIGHT PRESCRIPTIONS INNOVATORS, LLC, Altadena, CA (US)

(72) Inventors: Pablo Benitez, Madrid (ES); Juan Carlos Minano, Madrid (ES); Pablo Zamora, Madrid (ES); Joao Mendes Lopes, Madrid (ES); Julio C. Chaves, Coimbra (PT); Ruben Mohedano, Madrid (ES)

(73) Assignee: LIGHT PRESCRIPTIONS INNOVATIONS, LLC., Altadena, CA (US)

(21) Appl. No.: 14/394,975

(22) PCT Filed: Apr. 16, 2013
(86) PCT No.: PCT/US13/36771

§ 371 Date: Oct. 16, 2014

Related U.S. Application Data
(60) Provisional application No. 61/687,002, filed on Apr. 16, 2012.

(51) Int. Cl. H01L 31/054

(52) U.S. Cl. CPC H01L 31/0543
USPC 136/259

(57) ABSTRACT

One example of a solar voltaic concentrator has a primary Fresnel lens with multiple panels, each of which forms a Kohler integrator with a respective panel of a lenticular secondary lens. The resulting plurality of integrators all concentrate sunlight onto a common multi-junction photovoltaic cell. The integrators provide matching illumination in the different wavebands required by the different junctions. Luminaires using a similar geometry are also possible.

### CROSS REFERENCE TO RELATED APPLICATION

This application claims benefit of U.S. Provisional Patent Application No. 61/687,002 titled “Domed Fresnel Köhler Concentrator,” filed Apr. 16, 2012 by Benitez and Miñano, which is incorporated herein by reference in its entirety.

Reference is made to commonly-assigned U.S. Provisional Patent Applications No. 61/115,892 titled “Köhler Concentrator”, filed Nov. 18, 2008, No. 61/268,129 filed Jun. 8, 2009, of the same title, both in the names of Miñano et al., and No. 61/278,476, titled “Köhler concentrator azimuthally combining radial-Köhler sub-concentrators”, filed Oct. 6, 2009 in the name of Benitez et al., and ensuing U.S. Pat. No. No. 8,000,018 titled “Köhler Concentrator”, issued Aug. 16, 2011, which are incorporated herein by reference in their entirety.

Reference is made to commonly-assigned International Patent Applications Nos. PCT/US 2006/029464 (WO 2007/016363) to Miñano et al. and PCT/US 2007/063522 (WO 2007/103994) to Benitez et al. which are incorporated herein by reference in their entirety.

Embodiments of the devices described and shown in this application may be within the scope of one or more of the following U.S. Patents and Patent Applications and/or equivalents in other countries: U.S. Pat. No. 6,639,733, issued Oct. 28, 2003 in the names of Miñano et al., and U.S. Pat. No. 7,460,985 issued Dec. 2, 2008 in the names of Benitez et al.; WO 2007/016363 mentioned above, and US 2008/0316761 of the same title published Dec. 25, 2008 also in the names of Miñano et al; WO 2007/103994 titled “Multi-Junction Solar Cells with a Homogenizer System and Coupled Non-Imaging Light Concentrator” published Sep. 13, 2007 in the names of Benitez et al; US 2008/0223443, titled “Optical Concentrator Especially for Solar Photovoltaic” published Sep. 18, 2008 in the names of Benitez et al.; and US 2009/0071467 titled “Multi-Junction Solar Cells with a Homogenizer System and Coupled Non-Imaging Light Concentrator” published Mar. 19, 2009 in the names of Benitez et al.

### GLOSSARY

Primary Optical Element (POE)—Optical element (which may be one surface of a refractive element) that receives the light from the sun or other source and concentrates it towards the Secondary Optical Element.

Secondary Optical Element (SOE)—Optical element (which may be one surface of a refractive element) that receives the light from the Primary Optical Element and concentrates it towards the solar cell or other target.

Köhler integrator—Strictly, an optical device in which a primary optical element images a source onto a secondary optical element, and the secondary optical element images the primary optical element onto a target. In the present specification, as is explained below, the focal point of the primary optical element is deliberately not exactly coincident with the secondary optical element.

Parallel acceptance angle (αₚ)—For a flat, rectangular solar cell, the angle with respect to the perfect-aim direction of incident rays in a plane containing the perfect-aim direction and parallel to two sides of the solar cell, at which the cell photocurrent drops by 10% compared with an equal incident irradiation along the perfect-aim direction.

Diagonal acceptance angle (α_{d})—Angle with respect to the perfect-aim direction of incident rays in a plane parallel to the perfect-aim direction and containing one diagonal of the solar cell, at which the cell photocurrent drops by 10%.

Geometrical concentration (Cg)—Ratio of the projected area of the POE normal to the sun center direction to the cell area.

Concentration-Acceptance Product (CAP)—A parameter associated with any solar concentrating architecture, and which is defined as the product of the square root of the geometrical concentration times the sine of the acceptance angle (being the minimum of the parallel and diagonal acceptance angles). Some optical architectures have a higher CAP than others, enabling higher concentration and/or higher acceptance angle. For a specific architecture, the CAP is nearly constant when the geometrical concentration is changed, so that increasing the value of one parameter lowers the other.

Fresnel Facet—Element of a discontinuous-slope lens that deflects light by refraction.

Cartesian Oval—A curve (strictly a family of curves) used in imaging and non-imaging optics to transform a given bundle of rays into another predetermined bundle. See Reference [10], page 185, Reference [14].

Perfect-aim position—A central direction for incoming collimated light, or incoming sunlight (source diameter 0.5° centered on the nominal direction), away from which performance falls off in all directions. In all the embodiments described below, the perfect-aim position is a line of intersection of symmetry planes for the overall concentrator, but not necessarily for individual segments. However, the rate at which performance falls off may be different in different planes, see for example αₚ and α_{d} above.

Uniformity—The ratio of the minimum to maximum irradiance on the cell with the sun centered on the perfect-aim position.

### BACKGROUND

Triple-junction photovoltaic solar cells are expensive, making it desirable to operate them with as much concentration of sunlight as practical. However, the efficiency of currently available multi-junction photovoltaic cells suffers when the local concentration of incident radiation surpasses ˜1,000-2,000 suns. Some concentrator designs of the prior art have so much non-uniformity of the flux distribution on the cell that “hot spots” up to 20× the average concentration (9,000-11,000× concentration with average concentration of 500×) occur, greatly limiting the maximum average concentration that is commercially viable.

Good irradiance uniformity on the solar cell can potentially be obtained using a long light-pipe homogenizer, which is a well known method in classical optics. See Reference [1]. When a light-pipe homogenizer is used, the solar cell is glued to one end of the light-pipe and the light reaches the cell after some bounces on the light-pipe walls. The light distribution on the cell becomes more uniform as the length of the light-pipe is increased. The use of light-pipes for concentrating photo-voltaic (CPV) devices, however, has some drawbacks. A first drawback is that in the case of high illumination angles the reflecting surfaces of the light-pipe must be metalized, which reduces optical efficiency relative to the near-perfect reflectivity of total internal reflection off a polished surface in a dielectric-based light pipe. A second drawback is that for good homogenization a relatively long light-pipe is necessary, but increasing the length of the light-pipe both increases its absorption and reduces the mechanical stability of the apparatus. A third drawback is that light pipes are unsuitable for relatively thick (small) cells because of lateral light spillage from the edges of the bonding material holding the cell to the end of the light pipe (typically made of silicone rubber). Finally, the amount of bonding material used in the adhesion layer is critical. Too little material and there will be an air gap above a portion of the cell, resulting in losses due to Fresnel reflections. Too much material will result in the aforementioned spillage issue. The smaller the area of the cell, the greater proportion of the solar radiation is lost through spillage. Light-pipes have nevertheless been proposed several times in CPV systems, see References [2], [3], [4], [5], [6], and [7], which use a light-pipe length much longer than the cell size, typically 4-5 times.

Another strategy for achieving good uniformity on the cell is Köhler illumination. This technique can solve, or at least mitigate, uniformity issues without compromising the acceptance angle and without increasing the difficulty of assembly.

The first photovoltaic concentrator using Köhler integration was proposed (see Reference [8]) by Sandia Labs in the late 1980′s, and subsequently was commercialized by Alpha Solarco. That design used a standard radial concentric Fresnel lens as its primary optical element (POE) and an imaging single surface lens (called SILO, for SIngLe Optical surface) that encapsulates the photovoltaic cell was its secondary optical element (SOE). That approach used two imaging optical lenses (the Fresnel lens and the SILO) where the SILO is placed at the focal plane of the Fresnel lens and the SILO images the Fresnel lens (which is uniformly illuminated) onto the photovoltaic cell. Thus, if the cell is square the primary can be square trimmed without losing optical efficiency.

Despite the simplicity and high uniformity of illumination on the cell, the practical application of the Sandia Labs system is limited to low concentrations because it has a low concentration-acceptance product of approximately 0.3 (±1° at 300 ×). The low acceptance angle, even at a concentration ratio of only 300×, arises because the imaging secondary cannot accommodate high illumination angles on the cell.

Another previously proposed Köhler approach uses 4 optical surfaces, to obtain a photovoltaic concentrator for high acceptance angle and relatively uniform irradiance distribution on the solar cell (see Reference [9]). The POE of this concentrator is a double aspheric imaging lens, that images the sun onto the aperture of a SOE. Suitable for a secondary optical element is the SMS designed RX concentrator described in References [10], [11], [12]. This is an imaging element that works near the thermodynamic limit of concentration. This concentrator was of only academic interest, because neither the double aspheric element nor the RX concentrator are economically feasible for practical application, and the thermal management of the photovoltaic cells is also impractical in such a configuration.

In contrast to the previous Köhler approaches, in U.S. Pat. No. 8,000,018 B2 some of the inventors herein found a practical solution to increase the concentration-acceptance product. It consists in dividing the POE and SOE into sectors that provide independent Köhler channels, so each SOE sector needs to manage only a correspondingly smaller field of view and provide a correspondingly smaller concentration. Additionally, the multi-channel approach provided a further improvement and robustness due to the superposition principle: the degradation for any reason of one of the POE images is less noticeable than in the single-channel case (as was an issue with the SILO mentioned before) due to its smaller contribution to the total irradiance produced.

The most remarked embodiment in U.S. Pat. No. 8,000,018 B2 consisted in a 4-fold symmetric flat Fresnel lens and a 4-fold single-surface secondary lens. That device was conceived designing each Fresnel lens quadrant using a single wavelength. The position of the monochromatic focus was indicated to be located on the surface of the SOE, or alternatively deeper inside the bulk of the SOE, closer to a certain chord. There was no indication of a polychromatic design taking into account the different responses of the optical elements to the different spectral bands of a multi junction solar cell, the combined behavior of which is strongly non-linear.

Such polychromatic optimization has not been applied either to other related architecture, as a 9-fold Fresnel Köhler design also mentioned in U.S. Pat. No. 8,000,018 B2.

Although most Fresnel lenses used in this application are flat, better concentration-acceptance angle product has been achieved with rotationally symmetric domed lenses [5].

As is described in commonly assigned US 2010/0269885, obtaining optimum efficiency from a multi-junction solar cell can require very careful balancing of the irradiation of the different cells.

Most of the same or closely analogous problems arise, reversing the direction of the light rays, in producing a beam of white light from a luminaire with a white light source.

### SUMMARY

Embodiments of the present invention provide different photovoltaic concentrators that combine high geometric concentration, high acceptance angle, and high irradiance uniformity on the solar cell. In all the embodiments, the primary and secondary optical elements are each lenticulated to form a plurality of segments. A segment of the primary optical element and a segment of the secondary optical element combine to form a Köhler integrator. The multiple segments result in a plurality of Köhler integrators that collectively focus their incident sunlight onto a common target, such as a multi-junction photovoltaic cell, taking into account the response to the different spectral bands of a multi junction solar cell separately by means of a polychromatic optimization. Any hotspots are typically in different places for different individual Köhler integrators, with the plurality further averaging out the multiple hotspots over the target cell.

Embodiments of the present invention provide optical devices comprising: a multi-junction photovoltaic cell, wherein each junction is operative to convert light of a respective waveband into electricity; a refractive first optical element having a plurality of segments each arranged to focus incoming collimated light from a common source; and a second optical element having a plurality of segments, each arranged to direct light from a respective segment of the first optical element onto the photovoltaic cell; wherein the acceptance angles for incoming light of two of the said wavebands are within a ratio of 5:4 to 4:5.

The acceptance angles may be within the ratio of 5:4 to 4:5 for incoming light of the shortest and longest of the said wavebands, and advantageously for incoming light of all of the three or more wavebands.

If the cell, the first optical element (as projected into a plane perpendicular to a perfect-aim direction), and the segments of the first optical element (similarly projected) are all square, and are all aligned in the same direction, then the ratio of αₚ(top) to α_{d}(bottom) is desirably within the ratio of 5:4 to 4:5, where αₚ(top) is the acceptance angle of the shortest of the said wavebands, measured in a plane parallel to a side of the cell, α_{d}(bottom) is the acceptance angle of the longest of the said wavebands, measured in a plane containing a diagonal of the cell, and each of the said acceptance angles is defined as the angle between uniform incoming collimated light and a perfect-aim direction at which the light energy directed onto the cell is 90% of the energy directed onto the cell for identical incoming collimated light in the perfect-aim direction.

The first optical element may be a Fresnel or other discontinuous-surface lens. The segments of the Fresnel lens may then comprise Fresnel lenses with different centers. Alternatively, the first optical element may then comprise a sheet formed on one face with a Fresnel lens common to all of the segments, and formed on the other face with a separate continuous-slope lens for each segment. The Fresnel lens may be domed.

The CAP may be at least 0.45 for at least two of the wavebands, and preferably for all of the wavebands simultaneously.

The uniformity in the perfect-aim direction may be at least 0.5, better at least 0.67, preferably at least 0.8, for all wavebands.

An embodiment of the invention provides an optical device comprising: a primary optical element having a plurality of segments, which in an example are 4 in number; and a secondary optical element having a plurality of segments, which in an example are 4 lenticulations of an optical surface of a lens; wherein each segment of the primary optical element, along with a corresponding segment of the secondary optical element, forms one of a plurality of Uhler integrators. The plurality of Köhler integrators are arranged in position and orientation to direct light in multiple spectral bands from a common source onto a common target.

For example, in the case of a solar photovoltaic concentrator, the source is the sun. Whether it is the common source or the common target, the other may be part of the device or connected to it. For example, in a solar photovoltaic concentrator, the target may be a photovoltaic cell.

Embodiments of the invention also provide other forms of concentrator and collimator, including light collectors and luminaires, having similar optical properties. The common source, where the device is a light collector, or the common target, where the device is a luminaire, may be external to the device. The embodiments below are mainly intended for use as solar concentrators. For a luminaire, the source and target are typically interchanged, so that the light is highly concentrated at a source behind the “secondary” optical element, and is largely collimated on its way to an external target in front of the “primary” optical element.

Embodiments of the invention also provide methods of designing and making solar concentrators and other optical devices having the specified novel properties.

Embodiments of the present invention make it possible to simultaneously solve, or at least mitigate the consequences of not simultaneously solving, three problems:

1. The ray collection efficiency is to be as near 100% as possible for all of the three or more wavebands at normal (perfect-aim) incidence, that is, the three top, middle, and bottom junction rays are fully collected.

2. The irradiance on the cell for the three or more wavebands is balanced. This is not obtained in monochromatic designs without a homogenizing scheme such as Köhler integration, where typically the middle waveband produces a hot-spot at the center.

3. The overall acceptance angle for the three bands is to be maximized, which usually requires the acceptance angle for the three bands to be balanced as equally as possible, because the minimum of the three acceptance angles effectively limits the overall acceptance of the device.

### BRIEF DESCRIPTION OF THE DRAWINGS

FIG. 1 is a perspective view of the primary and secondary lenses of a previously proposed 4-fold Köhler concentrator.

FIG. 2 shows a set of three ray traces through the SOE of one embodiment of a solar concentrator for rays of three different wavelengths.

FIG. 3A shows a ray trace in the parallel direction for a top-junction band for an incidence angle equal to 0.95 α.

FIG. 3B shows a ray trace similar to that of FIG. 3A, but in the diagonal direction and for a bottom junction band.

FIG. 4A is a plot of irradiance against position over the area of a photovoltaic cell for the top junction band of a flat-POE design using the furthest point optimization for the SOE.

FIG. 4B is a plot similar to FIG. 4A for the bottom junction band.

FIG. 4C is a plot similar to FIG. 4A using the closest point optimization for the SOE.

FIG. 4D is a plot similar to FIG. 4C for the bottom junction band.

FIG. 5A is a perspective view of the primary and secondary lenses of a RR domed Fresnel Köhler concentrator.

FIG. 5B is an enlarged view of the SOE of FIG. 5A, showing a ray trace.

FIG. 6 is a diagram in axial section illustrating the design of a domed concentrator.

FIG. 7A is a 3D plot of irradiance for the top junction band of a concentrator with a domed POE optimized for maximum uniformity.

FIG. 7B is a plot similar to FIG. 7A for the bottom junction band.

FIG. 7C is a 3D plot of irradiance for the top junction band of a concentrator with a domed POE optimized for maximum CAP.

FIG. 7D is a plot similar to FIG. 7C for the bottom junction band.

FIG. 8A shows plan and perspective views of a circular domed Fresnel lens with four segments formed by lenticulations on the upper surface, and a common non-rotationally symmetric (spiral) Fresnel lens on the underside.

FIG. 8B is a perspective view from above of a square Fresnel lens taken from the circular lens of FIG. 8A.

FIG. 9A is a perspective view of the primary and secondary lenses of a 2-segment RR Fresnel Köhler concentrator.

FIG. 9B is an enlarged view of the SOE of FIG. 9A, showing a ray trace.

FIG. 10 is a perspective view of the primary and secondary lenses of a 9-segment RR Fresnel Köhler concentrator, and two different enlarged views of the SOE, with and without ray trace.

### DETAILED DESCRIPTION OF THE EMBODIMENTS

A better understanding of various features and advantages of the present invention may be obtained by reference to the following detailed description of embodiments of the invention and accompanying drawings, which set forth illustrative embodiments in which various principles of the invention are utilized.

The primary optical elements (POE) described in these embodiments are formed into segments, exhibiting multi-fold symmetry. In the embodiments taught in this application the secondary optical elements (SOE) have the same multi-fold symmetry as the respective POE. Each segment of the POE, along with a corresponding segment of the SOE, forms one of a plurality of Köhler integrator segments. The plurality of Kohler integrator segments combine to concentrate incoming sunlight on a common photovoltaic cell.

Presently available solar cells for solar concentrators use three junctions, usually referred to as top, middle and bottom, which are sensitive to different spectral bands of the solar radiation. The semiconductor physics of the junction determine the minimum photon energy (maximum wavelength) of light that the junction can convert to electricity. Typically, the top junction is sensitive from 350 to 690 nm, the middle junction from 690 nm to 900 nm, and the bottom junction beyond 900 nm (A germanium bottom junction can in principle use light down to about 1800 nm, while an InGaAs or InGaAsNSb bottom junction can use light down to only about 1400 nm.), the transition between the cell bands not necessarily being abrupt. When the POE is a mirror, the directions of the reflected rays are not dependent on the wavelength, and a monochromatic concentrator design is enough to predict to full spectrum performance.

However, in all the present embodiments, the POE is refractive, and the variation of the refractive index of the lens material with wavelength (usually called material dispersion, responsible for the chromatic aberration in imaging optics) causes rays of different wavelengths to be refracted towards different directions, reaching different points of the SOE. For a solar concentrator, these wavelength-dependent ray deviations for the different junction bands will cause two effects that should be taken into account: (1) there may be three different acceptance angles for the different junctions; and (2) the irradiance distribution may also be different for the different junctions. The first effect has the consequence that the effective acceptance angle for the concentrator as a whole is the smallest of the three, limiting the CAP of the device. The second effect degrades the overall solar cell efficiency, because the three junctions operate in series and the least brightly illuminated junction limits the current output of the stack. When the irradiance distributions of the wavebands used by the three junctions differ, that minimum-brightness limitation occurs locally, only partially mitigated by lateral current flows, even when the total integrated illumination of the cell is the same for the three junctions.

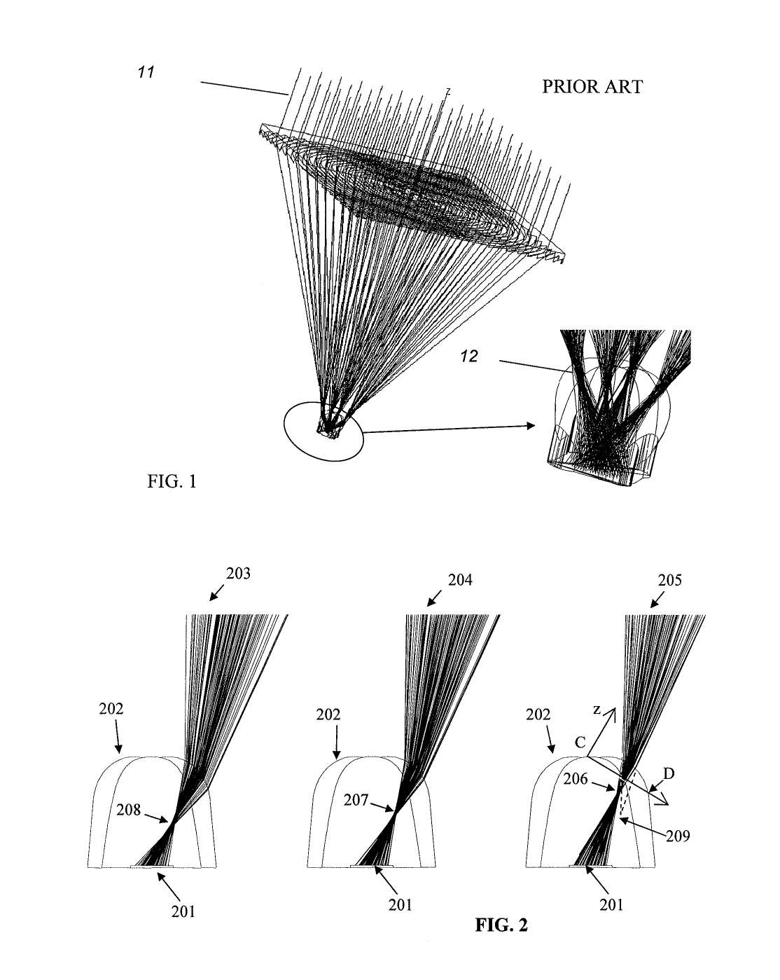

FIG. 1 shows one of the embodiments in the earlier U.S. Pat. No. 8,000,018 B2, in which the POE is a flat Fresnel lens with 4-fold symmetry. Each of the four Fresnel lens segments is part of a lens having rotational symmetry with respect to one of four axes that do not coincide with each other, and do not coincide with the center of the overall optical system. The normal-incidence rays 11 are split into four disconnected bundles to reach the four lobes of 4-fold symmetric SOE. The foci 12 of the POE lens segments are formed close to the front surface of the SOE. That design ignores chromatic dispersion, and assumes that tracing a single set of rays is sufficient.

The embodiments in the present application are optimized polychromatically to obtain solutions that can achieve high optical efficiency, and also correct the two effects mentioned above. That is to say, they can achieve as additional performance targets that: (1) the concentrator acceptance angle α, given by the smallest acceptance angle of the three junctions, is maximum, and (2) the irradiance distributions of the three junctions are very similar.

Even though the optimization described herein can be applied to a general N×M symmetric design, three specific preferred embodiments are included in this invention: a 2×2 symmetric with flat or dome Fresnel primary, which will be referred to as 4-fold for short; a 3×3 symmetric with a flat or dome Fresnel lens, which will be referred to as 9-fold for short; and a 2×1 symmetric with flat or dome Fresnel primary, which will be referred to as 2-fold for short.

The performance target (1) is obtained by the POE optimization. In order to illustrate this optimization, FIG. 2 shows a side view, in cross-section along a diagonal, of a 4-fold SOE 202 with a triple junction cell 201 being illuminated by the rays 205 of the top junction waveband, rays 204 of the middle junction waveband, and rays 203 of the bottom junction waveband. The POE (not shown in FIG. 2) is assumed to be a Fresnel lens. The focal regions are located in three very different positions, 206, 207 and 208, shallowest for the top junction focus 206 and deepest into the SOE for the bottom junction focus 208.

While in U.S. Pat. No. 8,000,018 B2 only a single focal region was mentioned, the polychromatic optimization disclosed here will take into account the positions of the three foci. In the case of a flat Fresnel POE, their positions cannot be controlled independently, so we can specify the position of one focus and calculate the other two.

One focus can preferably be specified as the point where light of the chosen color would notionally be focused by the POE if the further refraction of the light rays by the SOE did not intervene. For instance, point 209 in FIG. 2 corresponds to such a notional focus for light of wavelength 550 nm. The two coordinates (xₘ,zₘ) of point 209 in the tilted coordinate system x-z shown in FIG. 2 constitute the two parameters to vary for achieving performance target (1). Therefore, the objective is to solve the mathematical problem of finding the maximum of the two-variable function α(xₘ,zₘ). Since the definition of α=min{α(top), α(middle), α(bottom)} is very non-linear and its derivatives are not continuous, it is useful to visualize the overall shape of this function. For instance, in the case of 4-fold embodiments, the following inequalities hold in the neighborhood of the optimum:

αₚ(top)<αₚ(middle)<αₚ(bottom)

α_{d}(bottom)<α_{d}(middle)<α_{d}(top)

∂αₚ(top)/∂xₘ>0

∂α_{d}(bottom)/∂αxₘ<0

where αₚ and α_{d} denote the parallel and diagonal acceptance angles defined in the glossary. The first two equation lines indicate that the parallel acceptance angle for the top (short wavelength) junction is smaller than the parallel acceptances of the other two junctions, while for the diagonal direction the bottom junction is the limiting one.

The last two equation lines indicate that, for constant zₘ, when xₘ increases, the limiting parallel acceptance angle αₚ(top) increases while the limiting parallel acceptance angle α_{d}(bottom) decreases. Therefore, for each zₘ, there is compromise that is solved at the value of xₘ at which αₚ(top)=α_{d}(bottom) and then the acceptance angle α will be maximum. Therefore, we have found that the maximum desired in target (1) is obtained when the top and bottom acceptance angles are balanced.

The previous calculation can be done now with varying zₘ, and thus we can find the value of zₘ at which the coincident acceptance angle αₚ(top)=α_{d}(bottom) is a maximum, leading to the absolute maximum desired. Note that since α(top)=min{αₚ(top), α_{d}(top)} and α(bottom)=min{αₚ(bottom), α_{d}(bottom)}, we get that α=α(top)=α(bottom)<α(middle).

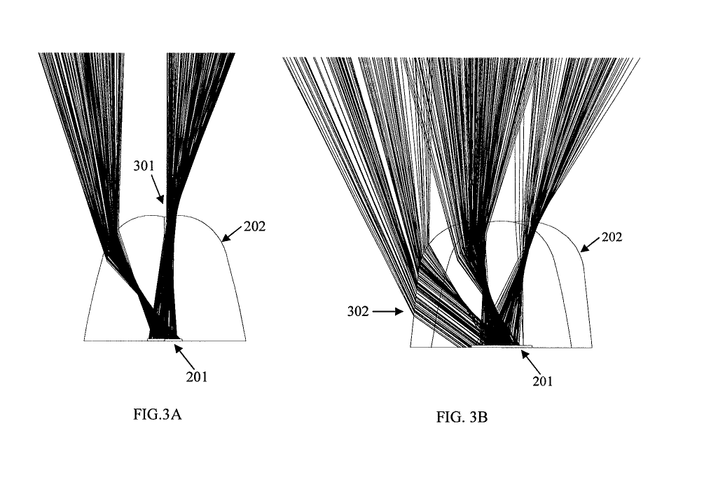

FIG. 3A shows the ray trace for the top junction spectral band on an optimized design at an incidence angle equal to 0.95α along the parallel direction. FIG. 3B shows the ray trace at the same incidence angle 0.95α but for the bottom junction spectral band along the diagonal direction. The 10% drop that will occur at the incidence angle α in both direction will occur when the ray 301 that enters the SOE nearest the top cusp of the SOE reaches the adjacent lobe in the top junction parallel case (FIG. 3A), and when the ray 302 that enters the SOE lowest down misses the target cell in the bottom junction diagonal case (FIG. 3B).

Since the refractive index of typical POE lens materials is not very different from middle to bottom junction bands, the focb 207 and 208 in FIG. 2 are relatively close and the middle and bottom acceptance angles are also close. As a consequence, instead of making the parallel top acceptance angle equal to the diagonal bottom acceptance angle, the parallel top and diagonal middle acceptance angles can be made equal. This is especially adequate for the case of solar cells in which there is an excess of bottom junction photocurrent (as in commercially available GaInP—GaInAs—Ge cells), so that the bottom-junction current is unlikely to be limiting.

In U.S. Pat. No. 8,000,018, only a monochromatic design is disclosed, and there is no mention of different parallel and diagonal acceptance angles. In U.S. Pat. No. 8,000,018, we recommended locating the single focal point either on the surface of the SOE or along the chord joining the edges of the meridional curve through the optical axis of the segment, which corresponds to a point of the line zₘ=0 in the present specification.

As will now be shown with an example, that monochromatic design with those focus selections leads to a very low acceptance angle compared to the present polychromatic optimization, and to a poor balance between the acceptance angles of the top, middle, and bottom junctions.

Two 4-fold devices with a flat Fresnel lens were designed, both with geometrical concentration Cg=1024×, POE made of silicone on glass with dimensions 160 mm×160 mm, SOE made of Savosil glass with 21.8 mm average diameter, GaInP—GaInAs—Ge triple junction 5 mm×5 mm solar cell, and depth to POE diagonal ratio 1.08. One of the devices was designed with the polychromatic optimization just described, while the other device was designed using the procedure disclosed in U.S. Pat. No. 8,000,018.

To reproduce the monochromatic design of U.S. Pat. No. 8,000,018, the acceptance angle at the selected wavelength was maximized. The selected wavelength was 550 nm, which is centered for the top junction band. This wavelength is commonly used in optics because at that wavelength the refractive index takes approximately the value of the median of the distribution. The choice of the 550 nm wavelength was not stated in U.S. Pat. No. 8,000,018, but can be easily inferred from column 8, lines 40-50, where it is stated that a polychromatic ray trace analysis for the top junction band achieves an acceptance angle of ±1.43° and the monochromatic analysis ±1.47° . The proximity of these two values is consistent with the 550 nm selection.

Table 1 shows the comparison of the performance parameters of the two designs obtained with a ray-trace analysis:

TABLE 1

| | α (top) | α (middle) | α (bottom) | α | CAP | xₘ (mm) | zₘ (mm) |
|---|---|---|---|---|---|---|---|
| Polychromatic | ±0.90° | ±0.94° | ±0.90° | ±0.90° | 0.51 | 11.7 | −5.1 |
| optimization | | | | | | | |
| U.S. Pat. No. | ±0.92° | ±0.66° | ±0.63° | ±0.66° | 0.35 | 10.3 | 0 |
| 8,000,018 | | | | | | | |

The first noticeable difference between the results for the two devices is that the focus of the 550 nm rays in the present polychromatic optimization is 5.1 mm away from the zₘ=0 line, where the U.S. Pat. No. 8,000,018. This distance is as large as the cell side, indicating the substantial difference between this polychromatically optimized design and the ones disclosed in U.S. Pat. No. 8,000,018.

The second difference is that while the acceptance angle for the three junctions is very well balanced in the polychromatic design, the bottom and middle junction acceptance angles are 30% lower than the top junction acceptance angle in the concentrator of U.S. Pat. No. 8,000,018, so the imbalance is substantial.

The third remarkable difference is that the resulting concentrator acceptance angle, given by α=min{α(top), α(middle), α(bottom)}, and the CAP, are also 30% less in the device of U.S. Pat. No. 8,000,018.

For this comparison, the U.S. Pat. No. 8,000,018 concentrator was designed with the 550 nm focus located at the line zₘ=0, but, as mentioned before, in that patent we suggested as an alternative to locate the focus on the surface of the SOE. That alternative selection leads to an acceptance and CAP even lower than the ones shown in the above Table.

The POE and SOE materials selected for the previous example are of special interest at present due to their expected long term durability. However, they have a relatively low refractive index (silicone has n=1.41 and Savosil has n=1.46 at 550 nm) which makes their attainable acceptance angle and CAP lower than with alternative materials, specially for the low depth to POE diagonal ratio (1.08). For instance, using PMMA for the POE and B270 glass for the SOE (which have n=1.49 and n=1.52, respectively), which are also excellent candidates in terms of durability, with the same depth to POE diagonal ratio, the same design algorithm leads to a 15% higher CAP value in about 15% thanks to their higher refractive indices.

On the other hand, performance target (2), which is that the irradiance distributions of the three junctions must be very similar, is obtained by optimizing the SOE. In this case, a single third design parameter is enough to obtain excellent results, and that is the point along the cell diagonal to be imaged by each quadrant on its corresponding POE sector. A central wavelength can be used for the calculations since the SOE imaging required is very little affected by the chromatic dispersion due to the large field of view of view that the SOE is imaging. The actual optimum position depends on the specific embodiment.

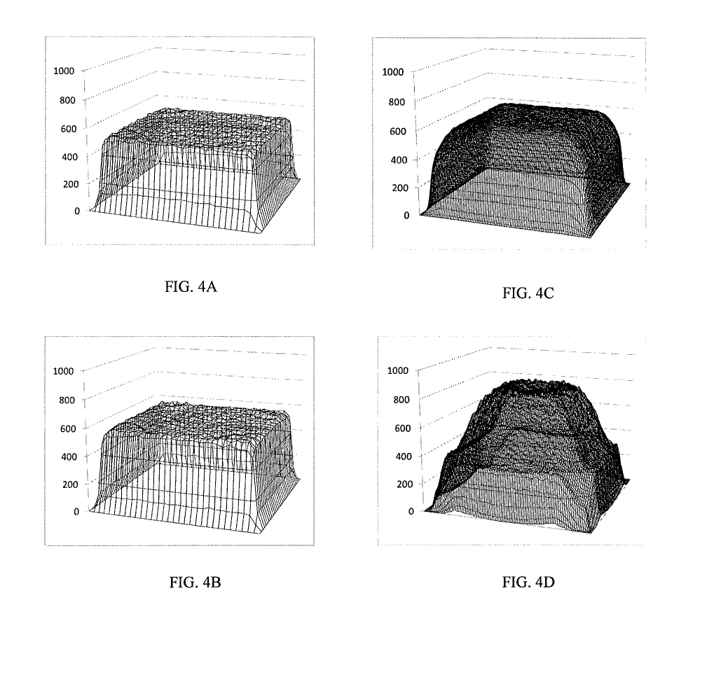

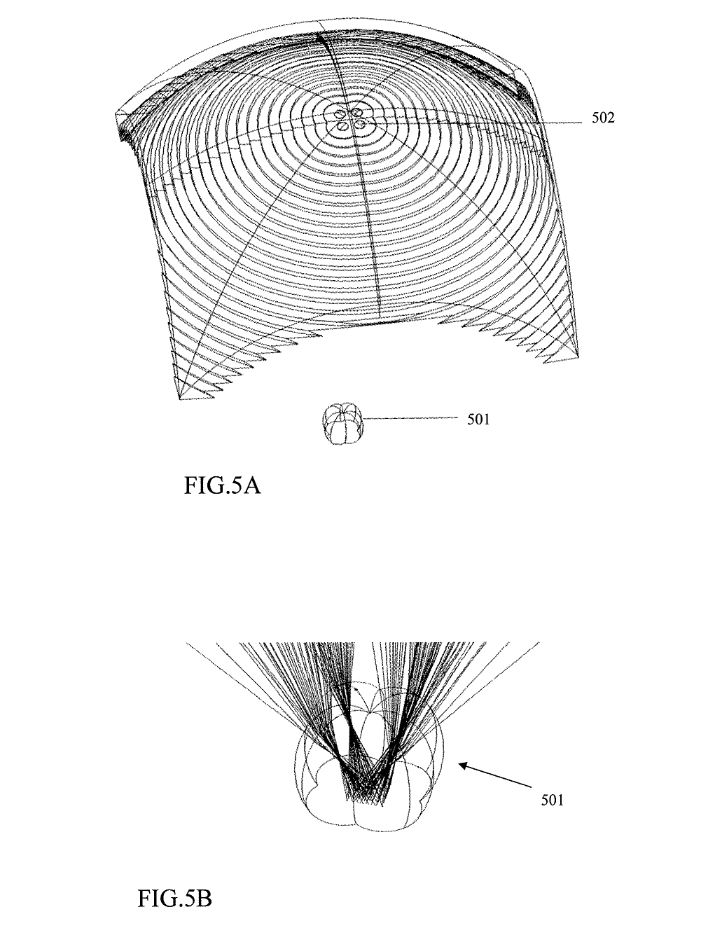

For instance, in the case of concentrators with flat POEs, being either 4-fold or 9-fold, the optimum is obtained when the selected cell diagonal point is the end of the diagonal furthest from the POE paired sector, as was disclosed in U.S. Pat. No. 8,000,018. However, for a domed POE the optimum point is the end of the diagonal closest to the paired sector. Although this selection is optimum for the balance of the irradiances (2), it is not optimum for other criteria, such as the acceptance angle. For instance, FIG. 4A and FIG. 4B show the irradiance for the extreme bands of the top and bottom junctions, respectively, of a flat-POE design with PMMA POE and B270 glass SOE using the furthest point selection, which is the optimum for target (2) and thus they look extremely alike. On the other hand, FIG. 4C and FIG. 4D show the same graphs for a flat-POE design using the closest point selection, in which a significantly poorer uniformity balance is visible. However, the furthest-point configuration of FIGS. 4A and 4B has a CAP=0.59, while the nearest-point configuration of FIGS. 4C and 4D achieves CAP=0.63.

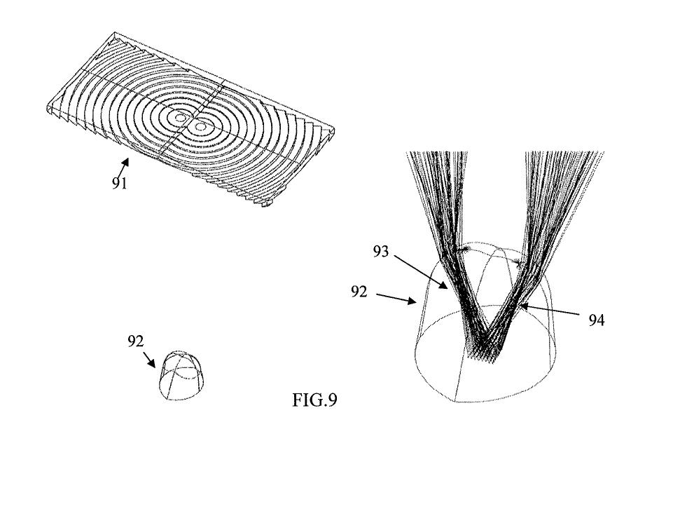

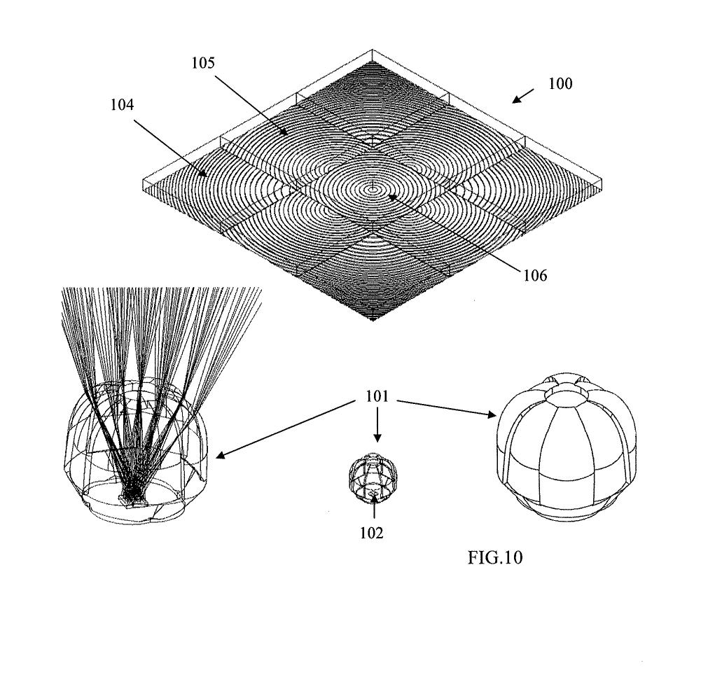

In addition, the present polychromatic optimization makes possible a much better uniformity over the three junctions. With previous monochromatic designs, as illustrated by Kritchman, Ref. [15], FIGS. 9 and 10, a too-perfect focusing at the nominal frequency sometimes resulted in a very non-uniform irradiation at that one frequency, and/or a wide variation in uniformity from one waveband to another.

The following Tables 2 and 3 show the numerical data describing the shape of the polychromatically optimized design just discussed whose performance data is given in the previous Table 1). For both the POE and the SOE, a Cartesian coordinates system is used, with the origin at the cell center and with the X and Y axes parallel to the cell sides, while the z axis is perpendicular to the cell plane. The size of the units is arbitrary, and in these units the cell active area is 5×5 while the POE is 160×160. Due to the 4-fold symmetry, the lenses need to be described only in the quadrant X>0 and Y>0. Both the POE and SOE are symmetric with respect to the plane X=Y.

The surface of the SOE has rotational symmetry with respect to the line joining the cell corner at X=Y=−7.071 and Z=0 with the POE corner at X=Y=113.2, Z=244.5. The SOE sag list is given in Table 2:

TABLE 2

| X = Y | Z |
|---|---|
| 10.905 | 7.974 |
| 10.505 | 12.5481 |
| 10.4675 | 12.9181 |
| 10.4194 | 13.2878 |
| 10.3603 | 13.6565 |
| 10.2901 | 14.0236 |
| 10.2084 | 14.3884 |
| 10.115 | 14.7502 |
| 10.0097 | 15.1082 |
| 9.89223 | 15.4617 |
| 9.76245 | 15.8099 |
| 9.62025 | 16.152 |
| 9.46554 | 16.4872 |
| 9.29828 | 16.8146 |
| 9.11848 | 17.1335 |
| 8.92617 | 17.4431 |
| 8.72146 | 17.7424 |
| 8.50449 | 18.0308 |
| 8.27547 | 18.3074 |
| 8.03465 | 18.5716 |
| 7.78232 | 18.8225 |
| 7.51885 | 19.0596 |
| 7.24464 | 19.2822 |
| 6.96015 | 19.4896 |
| 6.66587 | 19.6815 |
| 6.36235 | 19.8572 |
| 6.05018 | 20.0165 |

The Fresnel lens segment has an axis of rotational symmetry parallel to the Z axis, at X=Y=5.14468, and the vertices describing its polygonal profile are given in the following Table 3:

TABLE 3

| X = Y | Z |
|---|---|
| 5.14746 | 244.454 |
| 6.14746 | 244.459 |
| 6.14774 | 244.443 |
| 7.14746 | 244.459 |
| 7.14792 | 244.433 |
| 8.14746 | 244.459 |
| 8.14811 | 244.422 |
| 9.14746 | 244.459 |
| 9.14829 | 244.412 |
| 10.1475 | 244.459 |
| 10.1485 | 244.401 |
| 11.1475 | 244.459 |
| 11.1487 | 244.391 |
| 12.1475 | 244.459 |
| 12.1488 | 244.38 |
| 13.1475 | 244.459 |
| 13.149 | 244.37 |
| 14.1475 | 244.459 |
| 14.1492 | 244.36 |
| 15.1475 | 244.459 |
| 15.1494 | 244.349 |
| 16.1475 | 244.459 |
| 16.1496 | 244.339 |
| 17.1475 | 244.459 |
| 17.1498 | 244.328 |
| 18.1475 | 244.459 |
| 18.15 | 244.318 |
| 19.1475 | 244.459 |
| 19.1501 | 244.308 |
| 20.1475 | 244.459 |
| 20.1503 | 244.298 |
| 21.1475 | 244.459 |
| 21.1505 | 244.287 |
| 22.1475 | 244.459 |
| 22.1507 | 244.277 |
| 23.1475 | 244.459 |
| 23.1509 | 244.267 |
| 24.1475 | 244.459 |
| 24.1511 | 244.257 |
| 25.1475 | 244.459 |
| 25.1513 | 244.247 |
| 26.1475 | 244.459 |
| 26.1515 | 244.237 |
| 27.1475 | 244.459 |
| 27.1517 | 244.227 |
| 28.1475 | 244.459 |
| 28.1519 | 244.217 |
| 29.1475 | 244.459 |
| 29.1521 | 244.209 |
| 30.141 | 244.459 |
| 30.1456 | 244.209 |
| 31.0975 | 244.459 |
| 31.1021 | 244.209 |
| 32.021 | 244.459 |
| 32.0256 | 244.209 |
| 32.9148 | 244.459 |
| 32.9195 | 244.209 |
| 33.7819 | 244.459 |
| 33.7866 | 244.209 |
| 34.6246 | 244.459 |
| 34.6293 | 244.209 |
| 35.445 | 244.459 |
| 35.4497 | 244.209 |
| 36.2449 | 244.459 |
| 36.2496 | 244.209 |
| 37.0258 | 244.459 |
| 37.0306 | 244.209 |
| 37.7892 | 244.459 |
| 37.794 | 244.209 |
| 38.5363 | 244.459 |
| 38.5411 | 244.209 |
| 39.2681 | 244.459 |
| 39.273 | 244.209 |
| 39.9857 | 244.459 |
| 39.9905 | 244.209 |
| 40.6899 | 244.459 |
| 40.6947 | 244.209 |
| 41.3814 | 244.459 |
| 41.3863 | 244.209 |
| 42.0611 | 244.459 |
| 42.066 | 244.209 |
| 42.7295 | 244.459 |
| 42.7344 | 244.209 |
| 43.3873 | 244.459 |
| 43.3922 | 244.209 |
| 44.035 | 244.459 |
| 44.0399 | 244.209 |
| 44.6731 | 244.459 |
| 44.678 | 244.209 |
| 45.302 | 244.459 |
| 45.307 | 244.209 |
| 45.9223 | 244.459 |
| 45.9273 | 244.209 |
| 46.5342 | 244.459 |
| 46.5392 | 244.209 |
| 47.1382 | 244.459 |
| 47.1432 | 244.209 |
| 47.7346 | 244.459 |
| 47.7396 | 244.209 |
| 48.3236 | 244.459 |
| 48.3287 | 244.209 |
| 48.9057 | 244.459 |
| 48.9108 | 244.209 |
| 49.4811 | 244.459 |
| 49.4862 | 244.209 |
| 50.05 | 244.459 |
| 50.0552 | 244.209 |
| 50.6127 | 244.459 |
| 50.6179 | 244.209 |
| 51.1695 | 244.459 |
| 51.1747 | 244.209 |
| 51.7204 | 244.459 |
| 51.7256 | 244.209 |
| 52.2659 | 244.459 |
| 52.2711 | 244.209 |
| 52.8059 | 244.459 |
| 52.8111 | 244.209 |
| 53.3407 | 244.459 |
| 53.346 | 244.209 |
| 53.8706 | 244.459 |
| 53.8759 | 244.209 |
| 54.3956 | 244.459 |
| 54.4009 | 244.209 |
| 54.9159 | 244.459 |
| 54.9212 | 244.209 |
| 55.4316 | 244.459 |
| 55.4369 | 244.209 |
| 55.9429 | 244.459 |
| 55.9483 | 244.209 |
| 56.45 | 244.459 |
| 56.4554 | 244.209 |
| 56.9529 | 244.459 |
| 56.9583 | 244.209 |
| 57.4518 | 244.459 |
| 57.4572 | 244.209 |
| 57.9467 | 244.459 |
| 57.9522 | 244.209 |
| 58.4379 | 244.459 |
| 58.4433 | 244.209 |
| 58.9253 | 244.459 |
| 58.9308 | 244.209 |
| 59.4092 | 244.459 |
| 59.4147 | 244.209 |
| 59.8896 | 244.459 |
| 59.8951 | 244.209 |
| 60.3665 | 244.459 |
| 60.372 | 244.209 |
| 60.8401 | 244.459 |
| 60.8457 | 244.209 |
| 61.3105 | 244.459 |
| 61.3161 | 244.209 |
| 61.7778 | 244.459 |
| 61.7834 | 244.209 |
| 62.242 | 244.459 |
| 62.2476 | 244.209 |
| 62.7031 | 244.459 |
| 62.7087 | 244.209 |
| 63.1614 | 244.459 |
| 63.167 | 244.209 |
| 63.6167 | 244.459 |
| 63.6224 | 244.209 |
| 64.0693 | 244.459 |
| 64.075 | 244.209 |
| 64.5192 | 244.459 |
| 64.5249 | 244.209 |
| 64.9664 | 244.459 |
| 64.9721 | 244.209 |
| 65.411 | 244.459 |
| 65.4167 | 244.209 |
| 65.853 | 244.459 |
| 65.8588 | 244.209 |
| 66.2926 | 244.459 |
| 66.2984 | 244.209 |
| 66.7297 | 244.459 |
| 66.7355 | 244.209 |
| 67.1645 | 244.459 |
| 67.1703 | 244.209 |
| 67.5969 | 244.459 |
| 67.6027 | 244.209 |
| 68.027 | 244.459 |
| 68.0329 | 244.209 |
| 68.4549 | 244.459 |
| 68.4608 | 244.209 |
| 68.8806 | 244.459 |
| 68.8865 | 244.209 |
| 69.3041 | 244.459 |
| 69.3101 | 244.209 |
| 69.7256 | 244.459 |
| 69.7315 | 244.209 |
| 70.145 | 244.459 |
| 70.1509 | 244.209 |
| 70.5623 | 244.459 |
| 70.5683 | 244.209 |
| 70.9777 | 244.459 |
| 70.9837 | 244.209 |
| 71.3911 | 244.459 |
| 71.3972 | 244.209 |
| 71.8027 | 244.459 |
| 71.8087 | 244.209 |
| 72.2123 | 244.459 |
| 72.2184 | 244.209 |
| 72.6202 | 244.459 |
| 72.6263 | 244.209 |
| 73.0262 | 244.459 |
| 73.0323 | 244.209 |
| 73.4305 | 244.459 |
| 73.4366 | 244.209 |
| 73.833 | 244.459 |
| 73.8391 | 244.209 |
| 74.2338 | 244.459 |
| 74.24 | 244.209 |
| 74.6329 | 244.459 |
| 74.6391 | 244.209 |
| 75.0304 | 244.459 |
| 75.0366 | 244.209 |
| 75.4263 | 244.459 |
| 75.4325 | 244.209 |
| 75.8206 | 244.459 |
| 75.8268 | 244.209 |
| 76.2133 | 244.459 |
| 76.2196 | 244.209 |
| 76.6045 | 244.459 |
| 76.6108 | 244.209 |
| 76.9941 | 244.459 |
| 77.0005 | 244.209 |
| 77.3823 | 244.459 |
| 77.3887 | 244.209 |
| 77.7691 | 244.459 |
| 77.7754 | 244.209 |
| 78.1543 | 244.459 |
| 78.1607 | 244.209 |
| 78.5382 | 244.459 |
| 78.5446 | 244.209 |
| 78.9207 | 244.459 |
| 78.9271 | 244.209 |
| 79.3018 | 244.459 |
| 79.3083 | 244.209 |
| 79.6816 | 244.459 |
| 79.6881 | 244.209 |
| 80.06 | 244.459 |
| 80.0665 | 244.209 |
| 80.4372 | 244.459 |
| 80.4437 | 244.209 |
| 80.813 | 244.459 |
| 80.8196 | 244.209 |
| 81.1876 | 244.459 |
| 81.1942 | 244.209 |
| 81.561 | 244.459 |
| 81.5676 | 244.209 |
| 81.9331 | 244.459 |
| 81.9397 | 244.209 |
| 82.304 | 244.459 |
| 82.3106 | 244.209 |
| 82.6737 | 244.459 |
| 82.6804 | 244.209 |
| 83.0423 | 244.459 |
| 83.049 | 244.209 |
| 83.4097 | 244.459 |
| 83.4164 | 244.209 |
| 83.7759 | 244.459 |
| 83.7826 | 244.209 |
| 84.1411 | 244.459 |
| 84.1478 | 244.209 |
| 84.5051 | 244.459 |
| 84.5119 | 244.209 |
| 84.868 | 244.459 |
| 84.8748 | 244.209 |
| 85.2299 | 244.459 |
| 85.2367 | 244.209 |
| 85.5907 | 244.459 |
| 85.5975 | 244.209 |
| 85.9505 | 244.459 |
| 85.9573 | 244.209 |
| 86.3092 | 244.459 |
| 86.3161 | 244.209 |
| 86.6669 | 244.459 |
| 86.6738 | 244.209 |
| 87.0236 | 244.459 |
| 87.0305 | 244.209 |
| 87.3794 | 244.459 |
| 87.3863 | 244.209 |
| 87.7341 | 244.459 |
| 87.7411 | 244.209 |
| 88.0879 | 244.459 |
| 88.0949 | 244.209 |
| 88.4408 | 244.459 |
| 88.4478 | 244.209 |
| 88.7927 | 244.459 |
| 88.7997 | 244.209 |
| 89.1437 | 244.459 |
| 89.1507 | 244.209 |
| 89.4937 | 244.459 |
| 89.5008 | 244.209 |
| 89.8429 | 244.459 |
| 89.85 | 244.209 |
| 90.1912 | 244.459 |
| 90.1983 | 244.209 |
| 90.5386 | 244.459 |
| 90.5457 | 244.209 |
| 90.8852 | 244.459 |
| 90.8923 | 244.209 |
| 91.2309 | 244.459 |
| 91.238 | 244.209 |
| 91.5757 | 244.459 |
| 91.5829 | 244.209 |
| 91.9197 | 244.459 |
| 91.9269 | 244.209 |
| 92.2629 | 244.459 |
| 92.2702 | 244.209 |
| 92.6053 | 244.459 |
| 92.6126 | 244.209 |
| 92.9469 | 244.459 |
| 92.9542 | 244.209 |
| 93.2877 | 244.459 |
| 93.295 | 244.209 |
| 93.6277 | 244.459 |
| 93.6351 | 244.209 |
| 93.967 | 244.459 |
| 93.9743 | 244.209 |
| 94.3055 | 244.459 |
| 94.3128 | 244.209 |
| 94.6432 | 244.459 |
| 94.6506 | 244.209 |
| 94.9802 | 244.459 |
| 94.9876 | 244.209 |
| 95.3164 | 244.459 |
| 95.3239 | 244.209 |
| 95.6519 | 244.459 |
| 95.6594 | 244.209 |
| 95.9868 | 244.459 |
| 95.9942 | 244.209 |
| 96.3209 | 244.459 |
| 96.3284 | 244.209 |
| 96.6543 | 244.459 |
| 96.6618 | 244.209 |
| 96.987 | 244.459 |
| 96.9945 | 244.209 |
| 97.319 | 244.459 |
| 97.3266 | 244.209 |
| 97.6503 | 244.459 |
| 97.6579 | 244.209 |
| 97.981 | 244.459 |
| 97.9886 | 244.209 |
| 98.311 | 244.459 |
| 98.3187 | 244.209 |
| 98.6404 | 244.459 |
| 98.6481 | 244.209 |
| 98.9691 | 244.459 |
| 98.9768 | 244.209 |
| 99.2972 | 244.459 |
| 99.3049 | 244.209 |
| 99.6247 | 244.459 |
| 99.6324 | 244.209 |
| 99.9515 | 244.459 |
| 99.9593 | 244.209 |
| 100.278 | 244.459 |
| 100.286 | 244.209 |
| 100.603 | 244.459 |
| 100.611 | 244.209 |
| 100.928 | 244.459 |
| 100.936 | 244.209 |
| 101.253 | 244.459 |
| 101.261 | 244.209 |
| 101.577 | 244.459 |
| 101.584 | 244.209 |
| 101.9 | 244.459 |
| 101.908 | 244.209 |
| 102.222 | 244.459 |
| 102.23 | 244.209 |
| 102.545 | 244.459 |
| 102.553 | 244.209 |
| 102.866 | 244.459 |
| 102.874 | 244.209 |
| 103.187 | 244.459 |
| 103.195 | 244.209 |
| 103.507 | 244.459 |
| 103.515 | 244.209 |
| 103.827 | 244.459 |
| 103.835 | 244.209 |
| 104.147 | 244.459 |
| 104.155 | 244.209 |
| 104.465 | 244.459 |
| 104.474 | 244.209 |
| 104.784 | 244.459 |
| 104.792 | 244.209 |
| 105.101 | 244.459 |
| 105.11 | 244.209 |
| 105.419 | 244.459 |
| 105.427 | 244.209 |
| 105.735 | 244.459 |
| 105.744 | 244.209 |
| 106.052 | 244.459 |
| 106.06 | 244.209 |
| 106.367 | 244.459 |
| 106.376 | 244.209 |
| 106.683 | 244.459 |
| 106.691 | 244.209 |
| 106.997 | 244.459 |
| 107.006 | 244.209 |
| 107.312 | 244.459 |
| 107.32 | 244.209 |
| 107.625 | 244.459 |
| 107.634 | 244.209 |
| 107.939 | 244.459 |
| 107.947 | 244.209 |
| 108.251 | 244.459 |
| 108.26 | 244.209 |
| 108.564 | 244.459 |
| 108.572 | 244.209 |
| 108.876 | 244.459 |
| 108.884 | 244.209 |
| 109.187 | 244.459 |
| 109.196 | 244.209 |
| 109.498 | 244.459 |
| 109.507 | 244.209 |
| 109.809 | 244.459 |
| 109.817 | 244.209 |
| 110.119 | 244.459 |
| 110.127 | 244.209 |
| 110.428 | 244.459 |
| 110.437 | 244.209 |
| 110.738 | 244.459 |
| 110.746 | 244.209 |
| 111.046 | 244.459 |
| 111.055 | 244.209 |
| 111.355 | 244.459 |
| 111.363 | 244.209 |
| 111.663 | 244.459 |
| 111.671 | 244.209 |
| 111.97 | 244.459 |
| 111.979 | 244.209 |
| 112.277 | 244.459 |
| 112.286 | 244.209 |
| 112.584 | 244.459 |
| 112.593 | 244.209 |
| 112.89 | 244.459 |
| 112.899 | 244.209 |
| 113.196 | 244.459 |
| 113.196 | 249.034 |
| 5.14746 | 249.034 |

FIG. 5A and FIG. 5B disclose another preferred embodiment which consists of a 4-fold symmetric device in which the POE is a Fresnel lens 501 of a dome-like shape instead of flat. The additional degree of freedom to choose the curve of the overall profile of the Fresnel lens makes it possible in the polychromatic optimization to control the positions of two foci for two junctions instead of one.

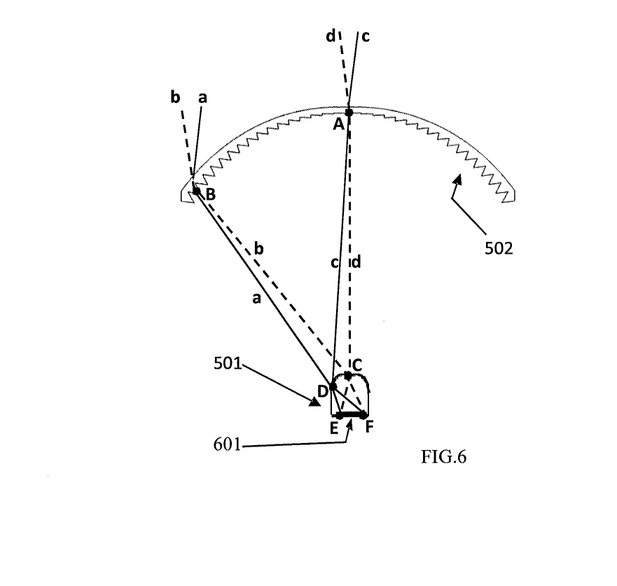

FIG. 6 illustrates the steps in the design of a domed 4-fold concentrator. First of all, point A on the POE, placed on the optical axis, is chosen. Then, point C of the SOE, on the symmetry axis, is chosen, and the SOE is designed as a Cartesian oval coupling spherical wavefronts with origins at A and at point E on the near edge of the cell passing through C. Next, point D is chosen as the point of the SOE where the meridional tangent line to the SOE forms a certain angle with the vertical direction (typically 5° to allow for easy demolding of the SOE part). Later, the POE is designed from A to B. One suitable method is described by Kritchman et al., Appl. Opt. 18, 2688-2695 (1979), Ref [15], which is incorporated herein by reference in its entirety, focusing parallel rays tilted+α(starting from ray c and ending with ray a) in D and focusing parallel rays tilted −α(starting in ray d and ending with ray b) in C, where a is the desired acceptance angle. Kritchman describes only the design of a cylindrical lens, but it is within the skill in the art at the present time to generalize Kritchman's method to a dome lens. Kritchman does not consider the possibility of a Köhler configuration, but can still be used to locate the primary focus 209.

In the present embodiments, the Kritchman method is modified as a polychromatic design, where rays focused in C are chosen to have a short wavelength in the solar spectrum (e.g. 450 nm, in the top junction band) and rays focused in D are chosen to have a long wavelength (e.g. 1,000 nm, in the bottom junction band). Rays impinging within ±α on point A, after being refracted in POE and SOE, will go to E. Then, analogously to the polychromatic optimization described, the coordinates of points F, C and the abscissa of D are considered as the free parameters that define the space in which the acceptance angle is maximized to achieve performance target (1).

Domed Fresnel designs can achieve lower depth to diameter ratios than flat Fresnel designs (0.7 to 0.9 for domed Fresnels compared with 0.9 to 1.2 for flat Fresnels) and higher CAPs due to the less constrained POE design (up to 0.73).

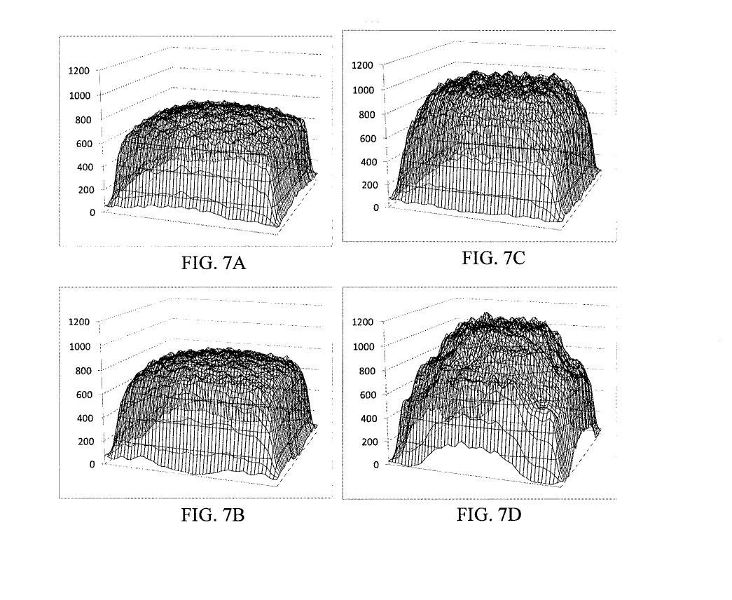

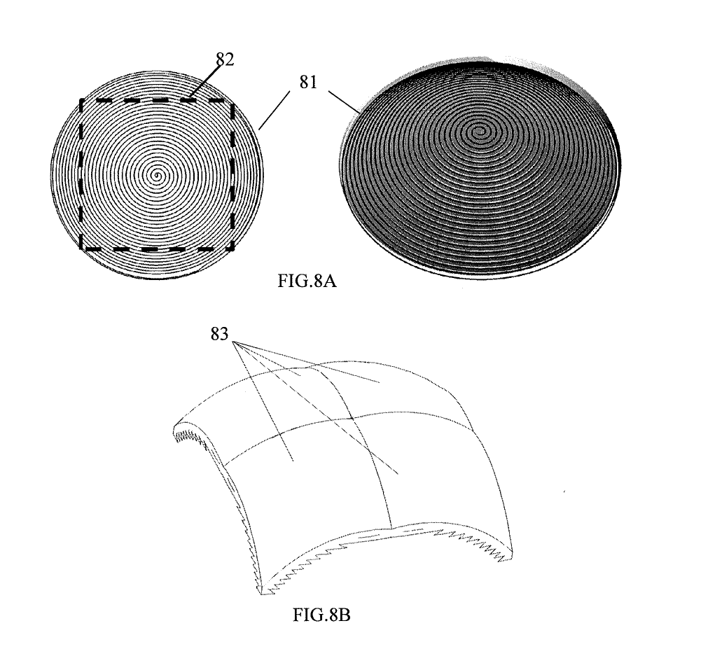

Regarding the balanced irradiance distributions intended in performance target (2), FIG. 7C and FIG. 7D show the irradiance of a design with Cg=1,234 for the extreme bands of the top and bottom junctions, respectively, of a dome designed according to the previous paragraphs. It shows that the irradiances are significantly less uniform and less alike than for the flat-Fresnel cases in FIG. 4A to 4D. The reason is that, since the lens is not flat, even if its projection on a plane normal to the sun direction is square, the angular region seen by the SOE lobes is not, and the image the SOE projects is very distorted and, because of the low depth to POE diagonal ratio, wavelength dependent. That design achieves a CAP=0.73. If the abscissae of C and D are diminished, it is possible to provide a much more balanced uniformity, as shown in FIG. 7A and FIG. 7B, but at a lower CAP=0.55.

Apart from the higher compactness and CAP, the dome Fresnel is advantageous over the flat one in its smaller SOE (this implies a lower absorption inside the material and lower cost in the glass molding process). However, since the combination of the lens convexity and high optical efficiency can result in the facets of the dome POE having negative draft angle, the manufacturing of the dome lens becomes challenging. One technique is based on the use of PMMA injection molding using a moveable mold, as the Japanese company Daido Steel has developed for rotationally symmetric lenses, see Ref. [5]. An alternative is shown in FIG. 8, in which the Fresnel interior face of the lens is made with a spiral profile 81 (which can be demolded by a combination of rotation and pull, as a screw), truncated to the square projected aperture 82. The exterior surface has the four lobes 83 to produce the desired beam separation. The spiral is constructed from a 2D polygonal profile contained in a meridional plane in three steps available in many CAD software packages: (a) a linearly varying spiral is generated passing through the concave vertices, (b) the same as (a) for the convex vertices, and (c) the facet profile is swept along the spirals using the them as rails. Of course, it is also possible to use the 4-fold front surface 83 of the POE in combination with a rotationally symmetric Fresnel inner surface.

The following two Tables 4 and 5 show the numerical data describing the shape of the polychromatically optimized dome design just discussed with CAP=0.73. For both the POE and the SOE, a Cartesian coordinates system is defined with the origin at the cell center and with the X and Y axes parallel to the cell sides, while the z axis is perpendicular to the cell plane. The size of the units is arbitrary, and in these units the cell active area is 5×5 while the POE is 176×176. Due to the 4-fold symmetry, the lenses need to be described only in the quadrant X>0 and Y>0. Both the POE and SOE are symmetric with respect to the plane X=Y.

The surface of SOE has rotational symmetry with respect to the line joining the cell corner at X=Y=7.071 and Z=0 with the POE vertex at X=Y=0, Z=200. The SOE sag list is given in the following Table 4:

TABLE 4

| X = Y | Z |
|---|---|
| 9.39701 | 5.93534 |
| 9.3411 | 6.49868 |
| 9.25159 | 7.08115 |
| 9.1247 | 7.67954 |
| 8.95669 | 8.28958 |
| 8.7439 | 8.90578 |
| 8.48307 | 9.52134 |
| 8.17144 | 10.1281 |
| 7.80715 | 10.7165 |
| 7.38944 | 11.2758 |
| 6.91901 | 11.7941 |
| 6.39831 | 12.2591 |
| 5.8317 | 12.6585 |
| 5.22555 | 12.9807 |
| 4.58818 | 13.2153 |
| 3.92959 | 13.3546 |
| 3.261 | 13.3936 |

The dome Fresnel lens has an axis of rotational symmetry parallel to the Z axis, at X=Y=5.211, and the points describing the inner polygonal profile and smooth outer profile are given in the following Table 5:

| X = Y | Z |
|---|---|
| 5.21094 | 200 |
| 10.2099 | 199.931 |
| 15.2015 | 199.648 |
| 20.1765 | 199.152 |
| 25.1259 | 198.445 |
| 30.0409 | 197.529 |
| 34.9128 | 196.406 |
| 39.7334 | 195.08 |
| 44.4947 | 193.555 |
| 49.1891 | 191.835 |
| 53.8095 | 189.925 |
| 58.3491 | 187.83 |
| 62.8016 | 185.556 |
| 67.1612 | 183.108 |
| 71.4226 | 180.493 |
| 75.5809 | 177.717 |
| 79.6316 | 174.787 |
| 83.5707 | 171.708 |
| 87.3947 | 168.487 |
| 91.1003 | 165.13 |
| 94.6847 | 161.645 |
| 98.1453 | 158.036 |
| 101.48 | 154.311 |
| 104.687 | 150.475 |
| 107.764 | 146.535 |
| 110.711 | 142.495 |
| 113.525 | 138.363 |
| 116.207 | 134.143 |
| 118.755 | 129.841 |
| 121.168 | 125.462 |
| 123.446 | 121.011 |
| 125.588 | 116.494 |
| 120.603 | 115.182 |
| 120.198 | 116.06 |
| 119.787 | 116.937 |
| 119.371 | 117.81 |
| 118.95 | 118.682 |
| 118.524 | 119.55 |
| 118.092 | 120.417 |
| 117.656 | 121.28 |
| 117.214 | 122.141 |
| 116.766 | 123 |
| 116.314 | 123.855 |
| 115.856 | 124.708 |
| 115.393 | 125.558 |
| 114.925 | 126.405 |
| 114.452 | 127.25 |
| 113.973 | 128.091 |
| 113.489 | 128.93 |
| 113 | 129.765 |
| 112.506 | 130.598 |
| 112.007 | 131.427 |
| 111.502 | 132.254 |
| 110.992 | 133.077 |
| 110.477 | 133.897 |
| 109.957 | 134.714 |
| 109.431 | 135.527 |
| 108.901 | 136.337 |
| 108.365 | 137.144 |
| 107.824 | 137.948 |
| 107.278 | 138.748 |
| 106.727 | 139.544 |
| 106.171 | 140.337 |
| 105.61 | 141.126 |
| 105.043 | 141.912 |
| 104.471 | 142.694 |
| 103.895 | 143.473 |
| 103.313 | 144.247 |
| 102.726 | 145.018 |
| 102.134 | 145.785 |
| 101.537 | 146.548 |
| 100.935 | 147.307 |
| 100.328 | 148.062 |
| 99.7157 | 148.813 |
| 99.0986 | 149.56 |
| 98.4764 | 150.303 |
| 97.8493 | 151.042 |
| 97.2172 | 151.777 |
| 96.5801 | 152.507 |
| 95.9381 | 153.233 |
| 95.2911 | 153.954 |
| 94.6392 | 154.672 |
| 93.9824 | 155.384 |
| 93.3207 | 156.093 |
| 92.6541 | 156.796 |
| 91.9827 | 157.495 |
| 91.3064 | 158.19 |
| 90.6253 | 158.88 |
| 89.9394 | 159.565 |
| 89.2487 | 160.245 |
| 88.5532 | 160.92 |
| 87.853 | 161.591 |
| 87.148 | 162.256 |
| 86.4383 | 162.917 |
| 85.7239 | 163.572 |
| 85.0049 | 164.223 |
| 84.2812 | 164.868 |
| 83.5528 | 165.508 |
| 82.8199 | 166.143 |
| 82.0824 | 166.773 |
| 81.3403 | 167.397 |
| 80.5937 | 168.016 |
| 79.8426 | 168.629 |
| 79.087 | 169.237 |
| 78.327 | 169.84 |
| 77.5625 | 170.436 |
| 76.7936 | 171.027 |
| 76.0204 | 171.613 |
| 75.2428 | 172.193 |
| 74.4609 | 172.766 |
| 73.6747 | 173.335 |
| 72.8842 | 173.897 |
| 72.0896 | 174.453 |
| 71.2907 | 175.003 |
| 70.4877 | 175.547 |
| 69.6806 | 176.085 |
| 68.8694 | 176.617 |
| 68.0541 | 177.143 |
| 67.2349 | 177.663 |
| 66.4116 | 178.176 |
| 65.5844 | 178.683 |
| 64.7533 | 179.183 |
| 63.9184 | 179.677 |
| 63.0796 | 180.164 |
| 62.237 | 180.645 |
| 61.3907 | 181.12 |
| 60.5407 | 181.588 |
| 59.687 | 182.049 |
| 58.8297 | 182.503 |
| 57.9689 | 182.951 |
| 57.1045 | 183.391 |
| 56.2366 | 183.825 |
| 55.3653 | 184.252 |
| 54.4906 | 184.672 |
| 53.6125 | 185.085 |
| 52.7312 | 185.491 |
| 51.8466 | 185.89 |
| 50.9588 | 186.281 |
| 50.0679 | 186.666 |
| 49.1738 | 187.043 |
| 48.2768 | 187.413 |
| 47.3767 | 187.776 |
| 46.4737 | 188.131 |
| 45.5679 | 188.479 |
| 44.6592 | 188.819 |
| 43.7477 | 189.152 |
| 42.8335 | 189.478 |
| 41.9167 | 189.796 |
| 40.9972 | 190.106 |
| 40.0753 | 190.409 |
| 39.1508 | 190.704 |
| 38.2239 | 190.991 |
| 37.2947 | 191.271 |
| 36.3631 | 191.543 |
| 35.4293 | 191.807 |
| 34.4933 | 192.063 |
| 33.5552 | 192.312 |
| 32.6151 | 192.552 |
| 31.673 | 192.785 |
| 30.7289 | 193.01 |
| 29.783 | 193.226 |
| 28.8353 | 193.435 |
| 27.8858 | 193.636 |
| 26.9347 | 193.828 |
| 25.982 | 194.013 |
| 25.0278 | 194.189 |
| 24.0721 | 194.358 |
| 23.115 | 194.518 |
| 22.1565 | 194.67 |
| 21.1969 | 194.814 |
| 20.236 | 194.949 |
| 19.274 | 195.077 |
| 18.311 | 195.196 |
| 17.347 | 195.307 |
| 16.382 | 195.41 |
| 15.4163 | 195.504 |
| 14.4497 | 195.591 |
| 13.4825 | 195.669 |
| 12.5146 | 195.738 |
| 11.5462 | 195.8 |
| 10.5773 | 195.853 |
| 9.60802 | 195.898 |
| 8.63837 | 195.934 |
| 7.66844 | 195.962 |
| 6.6983 | 195.983 |
| 5.72802 | 196 |

So far, the embodiments have had 2×2 symmetric units, but the polychromatic optimization described can be applied to other more general N×M schemes. FIG. 9 shows a 1×2 design, in which the rectangular POE lens 91 is divided into two segments that concentrate the sun light onto a two-lobe SOE lens 92, splitting the beam into two channels that create the two foci 93 and 94. Devices with N different from M have the capacity to produce different acceptance angles in the N and M directions. This is of interest for setting the high acceptance angle direction parallel to the elevation axis, at which the mechanical constraint is higher in usual rectangular arrays. The design in FIG. 9 has Cg=312× and acceptance angles of ±1.37° and 1.62° (larger in the direction of the long side of the POE rectangle).

The acceptance of the 1×2 concentrator may be optimized analogously with the 2×2 concentrators described above. Defining the “long parallel” direction as parallel to the edge that extends first along one segment of the primary optical element 91 and then along the other segment, and defining the “short parallel” direction as parallel to the orthogonal edges, the optimization can be done in three ways:

(1) The simplest approach, as in the 4-fold case, is to find the maximum at which α_long (top)=α_long (bottom) and maximum. In this case α_short (top) and α_short (bottom) will not in general be equal one to another.

(2) Use xₘ, and zₘ to adjust the two equations α_long (top)=α_long (bottom) and α_short (top)=α_short(bottom). In this case along will not be maximum.

(3) Find the maximum at which α_short (top)=α_short (bottom) and maximum. In this case α_long (top) and α_long (bottom) will not in general be equal one to another. This is the same as (1) exchanging long and short.

FIG. 10 shows a further embodiment of a Köhler integrating concentrator in the form of a 3×3 concentrator, for which the polychromatic optimization has to be applied. The POE is a Fresnel lens 100 comprising nine segments or sectors. The Fresnel lens is not fully rotationally symmetric, but comprises a symmetric central sector 106, four lateral sectors 105, each of them symmetric with each other relative to the Fresnel lens center, and four diagonal sectors 104, also symmetric with each other relative to the Fresnel lens center. The four lateral and four diagonal sectors may be made as an off-center square piece of a symmetric Fresnel lens. SOE lens 101 also comprises nine sectors, each aligned with corresponding sector of POE lens 100. All nine sector pairs send the sun rays within the acceptance angle to cell 102.

Compared to 4-fold flat Fresnel designs, the 9-fold produces a higher CAP (up to 0.65) in performance target (1) and an even better uniformity and irradiance balance in performance target (2). For instance, the 9-fold in FIG. 10 achieves Cg=1000× of geometrical concentration with an acceptance angle of ±1.18° (i.e. CAP=0.65). This device is attractive for solar cells 102 with specially high spectral sensitivity, as is expected to occur in future four and five junction solar cells.

With the design of their previous U.S. Pat. No. 8,000,018, the inventors have achieved a balance no better than 0.7:1 between the top and bottom junctions, and a CAP for the worst of the three wavebands no better than 0.40. They believe that a balance of 0.75:1 and a CAP of 0.45 would be obtainable by improved design. With the present devices, in contrast, a balance of at least 0.99:1 between the top and bottom junctions, and a CAP for the worst of the three wavebands of at least 0.63 are obtainable, even with a flat primary optical element.

Embodiments of the present invention consistently achieve a CAP greater than 0.45, and a uniformity (ratio of minimum to maximum irradiance on the cell with the sun centered on the perfect-aim position) of at least 0.5 for all wavebands simultaneously. The inventors have found that with proper design a uniformity of at least ⅔, and usually at least 0.8, is consistently achievable for realistic configurations.

### REFERENCES

[1] W. Cassarly, “Nonimaging Optics: Concentration and Illumination”, in the Handbook of Optics, 2nd ed., pp 2.23-2.42, (McGraw-Hill, New York, 2001)

[2] H. Ries, J. M. Gordon, M. Laxen, “High-flux photovoltaic solar concentrators with Kaleidoscope based optical designs”, Solar Energy, Vol. 60, No. 1, pp.11-16, (1997)

[3] J. J. O′Ghallagher, R. Winston, “Nonimaging solar concentrator with near-uniform irradiance for photovoltaic arrays” in Nonimaging Optics: Maximum Efficiency Light Transfer VI, Roland Winston, Ed., Proc. SPIE 4446, pp. 60-64, (2001)

[4] D. G. Jenkings, “High-uniformity solar concentrators for photovoltaic systems” in Nonimaging Optics: Maximum Efficiency Light Transfer VI, Roland Winston, Ed., Proc. SPIE 4446, pp. 52-59, (2001)

[5] http://www.daido.co.jp/en/products/cpv/technology.html

[6] http://www.solfocus.com/

[7] http://www.suncorepv.com/

[8] L. W. James, “Use of imaging refractive secondaries in photovoltaic concentrators”, SAND 89p-7029, Albuquerque, N. Mex., (1989)

[9] Chapter 13, “Next Generation Photovoltaics”, (Taylor & Francis, CRC Press, 2003)

[10] R. Winston, J. C. Miñano, P. Benitez, “Nonimaging Optics”, (Elsevier-Academic Press, New York, 2005)

[11] J. C. Miñano, P. Benitez, J.C. Gonzalez, “RX: a nonimaging concentrator”, Appl. Opt. 34, pp. 2226-2235, (1995)

[12] P. Benitez, J. C. Miñano, “Ultrahigh-numerical-aperture imaging concentrator”, J. Opt. Soc. Am. A, 14, pp. 1988-1997, (1997)

[13] J. C. Miñano, M. Hernández, P. Benitez, J. Blen, O. Dross, R. Mohedano, A. Santamaria, “Free-form integrator array optics”, in Nonimaging Optics and Efficient Illumination Systems II, SPIE Proc., R. Winston & T.J. Koshel ed. (2005)

[14] J. Chaves, “Introduction to Nonimaging Optics”, CRC Press, 2008, Chapter 17.

[15] E.M. Kritchman, A.A. Friesem, G. Yekutieli, “Highly Concentrating Fresnel Lenses”, Appl. Opt. 18, 2688-2695 (1979)

1. An optical device comprising:
a multi junction photovoltaic cell, wherein each junction is operative to convert light of a respective waveband into electricity;
a refractive first optical element having a plurality of segments each arranged to focus incoming collimated light from a common source; and
a second optical element having a plurality of segments, each arranged to direct light from a respective segment of the first optical element onto the photovoltaic cell;
wherein the acceptance angles for incoming light of two of the said wavebands are within a ratio of 5:4 to 4:5.

2. The optical device of claim 1, wherein the acceptance angles for incoming light of the shortest and longest of the said wavebands are within the ratio of 5:4 to 4:5.

3. The optical device of claim 1, wherein the acceptance angles for incoming light of all of the said wavebands are within the ratio of 5:4 to 4:5.

4. The optical device of claim 1, wherein the cell is square, the projection of the first optical element into a plane perpendicular to a perfect-aim direction is square, and the projections of the segments of the first optical element into the plane perpendicular to the perfect-aim direction are square.

5. The optical device of claim 4, wherein the ratio of αₚ(top) to α_{d}(bottom) is within the ratio of 5:4 to 4:5, where αₚ(top) is the acceptance angle of the shortest of the said wavebands, measured in a plane parallel to a side of the cell, α_{d}(bottom) is the acceptance angle of the longest of the said wavebands, measured in a plane containing a diagonal of the cell, and each of the said acceptance angles is defined as the angle between uniform incoming collimated light and a perfect-aim direction at which the light energy directed onto the cell is 90% of the energy directed onto the cell for identical incoming collimated light in the perfect-aim direction.

6. The optical device of claim 1, wherein the first optical element is a Fresnel lens.

7. The optical device of claim 6, wherein the segments of the Fresnel lens comprise Fresnel lenses with different centers.

8. The optical device of claim 6, wherein the first optical element comprises a sheet formed on one face with a Fresnel lens common to all of the segments, and formed on the other face with a separate continuous-slope lens for each segment.

9. The optical device of claim 6, wherein the Fresnel lens is domed.

10. The optical device of claim 1, wherein the CAP is at least 0.45 for at least two of the wavebands.

11. The optical device of claim 10, wherein the CAP is at least 0.45 for all of the wavebands.

12. The optical device of claim 1, wherein the uniformity in the perfect-aim direction is at least 0.5 for all wavebands.

13. The optical device of claim 12, wherein the uniformity in the perfect-aim direction is at least 0.67 for all wavebands.

14. The optical device of claim 13, wherein the uniformity in the perfect-aim direction is at least 0.8 for all wavebands.

15. The optical device of claim 1, wherein the second optical element is a front surface of a solid transparent body having the photovoltaic cell in contact with a rear surface; and wherein incoming collimated light is refracted by each segment of the first optical element towards a focus within the transparent body; and wherein if a chord is defined between end points of a meridional curve on the respective second optical element surface of the transparent body, said focus is between said chord and the photovoltaic cell for at least two of said wavebands.

16. The optical device of claim 15, wherein said focus is between said chord and the photovoltaic cell for all of said wavebands.

17. The optical device of claim 15, wherein the distance between said chord and said focus is at least equal to the length of side of the photovoltaic cell.

18. (canceled)
